(19) United States
(12) Patent Application Publication
(10) Pub. No.: US 2019/0230752 A1
(43) Pub. Date: Jul. 25, 2019

(54) DIELECTRIC HEATING APPARATUS

(71) Applicant: SHARP KABUSHIKI KAISHA, Sakai City, Osaka (JP)

(72) Inventors: YOSHINOBU TOMOMURA, Sakai City (JP); KENTARO TERASHIMA, Sakai City (JP)

(21) Appl. No.: 16/326,809

(22) PCT Filed: Feb. 16, 2017
(86) PCT No.: PCT/JP2017/005631

§ 371 Date: Feb. 20, 2019

(30) Foreign Application Priority Data
Oct. 27, 2016 (JP) 2016-210470

(51) Int. Cl. H05B 6/68; H05B 6/64; H05B 6/72; H03F 3/24

(52) U.S. Cl. CPC H05B 6/687; H05B 6/6417; H03F 3/245; H05B 6/72; H05B 6/6447

(57) ABSTRACT

A microwave heating cooker (1) is an example of a dielectric heating apparatus. The microwave heating cooker (1) includes a door that opens and closes a heating chamber, and a high-frequency power supply (10). The high-frequency power supply (10) includes: a high-frequency oscillation circuit (6); at least one semiconductor amplifier (3, 4) for amplifying a high-frequency signal from the high-frequency oscillation circuit (6); a door switch (9) (open/close detection unit) for detecting whether the door is open or closed; and a control unit (20) that stops the high-frequency oscillation circuit (6) when the door is opened.

### TECHNICAL FIELD

The present invention relates to a dielectric heating apparatus that processes food items by dielectric heating such as in heating and thawing.

### BACKGROUND ART

A dielectric heating apparatus, such as a microwave heating cooker, heats an item to be heated, or a dielectric, by means of high-frequency dielectric heating using a semiconductor device. A dielectric heating apparatus is configured to amplify the output of a high-frequency oscillator with multiple stages of high-frequency power amplifier circuits, and output high-frequency waves (for example, microwaves) into a heating chamber from an antenna.

For considerations such as user safety and prevention of radiation leakage, a dielectric heating apparatus that emits high-frequency waves into a heating chamber is required to stop generating high-frequency output when the heating chamber is opened. In a traditional dielectric heating apparatus such as a magnetron range, a mechanical switch that works in coordination with opening and closing of the door is used to cut off the AC power line when the door is opened.

PTL 1 proposes a door switch having a mechanical contact that works in coordination with the door to prevent transistor damage in a microwave processor having a normally ON transistor (FET). The microwave processor of this related art is configured so that the door switch contact opens, and the supply of direct-current (DC) voltage from a power supply unit to a power unit is instantaneously cut off when the door is opened.

### CITATION LIST

### Patent Literature

PTL 1: JP-A-2011-146143

### SUMMARY OF INVENTION

### Technical Problem

However, some high-frequency dielectric heating apparatuses are equipped with a high-frequency power supply having a large-capacity capacitor to enable a semiconductor amplifier to operate under a DC voltage with improved power factor. In such a configuration, the remaining energy in the capacitor is supplied to the semiconductor amplifier even after the AC power-supply line is cut when the door is opened. That is, it is not possible to stop high-frequency output at the very instant when the door is opened.

In order to instantaneously stop high-frequency output when the door is opened, it may be possible to cut the DC line with a mechanical switch when the door switch opens. However, because the DC line is carrying large current in a semiconductor amplifier outputting high-frequency waves, an arc may occur between the contacts of the mechanical switch upon cutting the DC line. An arc created between the contacts of the mechanical switch may result in the switch being incompletely cut off, and having a shorter life.

It is accordingly an object of an aspect of the present invention to provide a dielectric heating apparatus with which high-frequency output into a heating chamber can be stopped when the door is opened, while reducing the influence of an arc that occurs in a switch.

### Solution to Problem

A dielectric heating apparatus according to a first aspect of the present invention includes:

a door that opens and closes a heating chamber;

a high-frequency oscillation circuit;

at least one semiconductor amplifier for amplifying a high-frequency wave from the high-frequency oscillation circuit; and

a control unit or a switch that stops the high-frequency oscillation circuit when the door is opened.

A dielectric heating apparatus according to a second aspect of the present invention includes:

a door that opens and closes a heating chamber;

a high-frequency oscillation circuit;

a plurality of semiconductor amplifiers for amplifying a high-frequency wave from the high-frequency oscillation circuit, and including at least a first-stage semiconductor amplifier and a second-stage semiconductor amplifier;

a first switch for switching ON and OFF power supply to the first-stage semiconductor amplifier; and

a second switch for switching ON and OFF power supply to the second-stage semiconductor amplifier.

The first switch is switched ON when the door is closed. The first switch is switched OFF when the door is opened.

In the dielectric heating apparatus according to the second aspect of the present invention, the second switch may be switched OFF after the first switch is switched OFF.

A dielectric heating apparatus according to a third aspect of the present invention includes:

a heating chamber having an aperture;

a door that opens and closes the heating chamber;

a high-frequency oscillation circuit; and

a high-frequency wave irradiator that sends a high-frequency wave generated in the high-frequency oscillation circuit to the heating chamber through the aperture.

The aperture has an open/close mechanism. The open/close mechanism of the aperture closes when the door is opened.

The dielectric heating apparatus according to the third aspect of the present invention may be such that the open/close mechanism has an electromagnetic wave absorber on a side facing the high-frequency wave irradiator.

The dielectric heating apparatus according to any one of the first to third aspects of the present invention may be such that the high-frequency wave has a frequency of 0.3 GHz to 3 GHz, and that the dielectric heating apparatus includes an antenna that sends the high-frequency wave to an item to be heated.

The dielectric heating apparatus according to the first or second aspect of the present invention may be such that the high-frequency wave has a frequency of 3 MHz to 300 MHz, and that the dielectric heating apparatus includes at least two electrodes between which is placed an item to be heated, and that the high-frequency wave creates a high-frequency electric field between said at least two electrodes.

### Advantageous Effects of Invention

With a dielectric heating apparatus according to an aspect of the present invention, high-frequency output into a heating chamber can be stopped when the door is opened, while reducing the influence of an arc that occurs in a switch.

### BRIEF DESCRIPTION OF DRAWINGS

FIG. 1 is a perspective view showing the appearance of a heating cooker according to an embodiment of the present invention.

FIG. 2 is a perspective view showing the heating cooker according to the embodiment of the present invention with the door open.

FIG. 3 is a schematic view showing an inner configuration of the heating cooker according to First Embodiment of the present invention.

FIG. 4 is a circuit diagram showing a configuration of a high-frequency power supply provided in the heating cooker of FIG. 3.

FIG. 5 is a circuit diagram showing a configuration of a part of the high-frequency power supply of FIG. 4.

FIG. 6 is a circuit diagram showing an example of the operation of the high-frequency power supply provided in the heating cooker of FIG. 3.

FIG. 7 is a circuit diagram showing a configuration of a high-frequency power supply according to a variation of First Embodiment.

FIG. 8 is a schematic view showing an inner configuration of a heating cooker according to Second Embodiment of the present invention.

FIG. 9 is a circuit diagram showing a configuration of a high-frequency power supply provided in the heating cooker of FIG. 8.

FIG. 10 is a circuit diagram showing an example of the operation of the high-frequency power supply provided in the heating cooker of FIG. 8.

FIG. 11 is a schematic view showing an inner configuration of a defroster according to Third Embodiment of the present invention.

FIG. 12 is a circuit diagram showing a configuration of a high-frequency power supply provided in the defroster of FIG. 11.

FIG. 13 is a circuit diagram showing an example of the operation of the high-frequency power supply provided in the defroster of FIG. 11.

FIG. 14 is a schematic view showing an inner configuration of a defroster according to Fourth Embodiment of the present invention.

FIG. 15 is a circuit diagram showing a configuration of a high-frequency power supply provided in the defroster of FIG. 14.

FIG. 16 is a circuit diagram showing an example of the operation of the high-frequency power supply provided in the defroster of FIG. 14.

FIG. 17 is a perspective view showing a configuration of a heating cooker according to Fifth Embodiment of the present invention with the door of the heating compartment open.

FIG. 18 is a side schematic view of an open/close mechanism installed in the heating compartment of the heating cooker of FIG. 17.

FIG. 19 is a schematic view showing an inner configuration of the heating cooker of FIG. 17 with the door closed.

### DESCRIPTION OF EMBODIMENTS

Embodiments of the present invention are described below with reference to the accompanying drawings, in the following descriptions, like elements are given like reference numerals. Such like elements will be referred to by the same names, and have the same functions. Accordingly, detailed descriptions of such elements will not be repeated.

### First Embodiment

The present embodiment describes a microwave heating cooker (hereinafter, referred to simply as “heating cooker”) as an example of a dielectric heating apparatus according to an aspect of the present invention. The heating cooker dielectrically heats an item to be heated, such as food, using electromagnetic waves of a UHF frequency range of 2.4 GHz to 2.5 GHz. However, the electromagnetic frequency used in the dielectric heating apparatus of the present invention is not limited to this.

### Overall Configuration of Heating Cooker

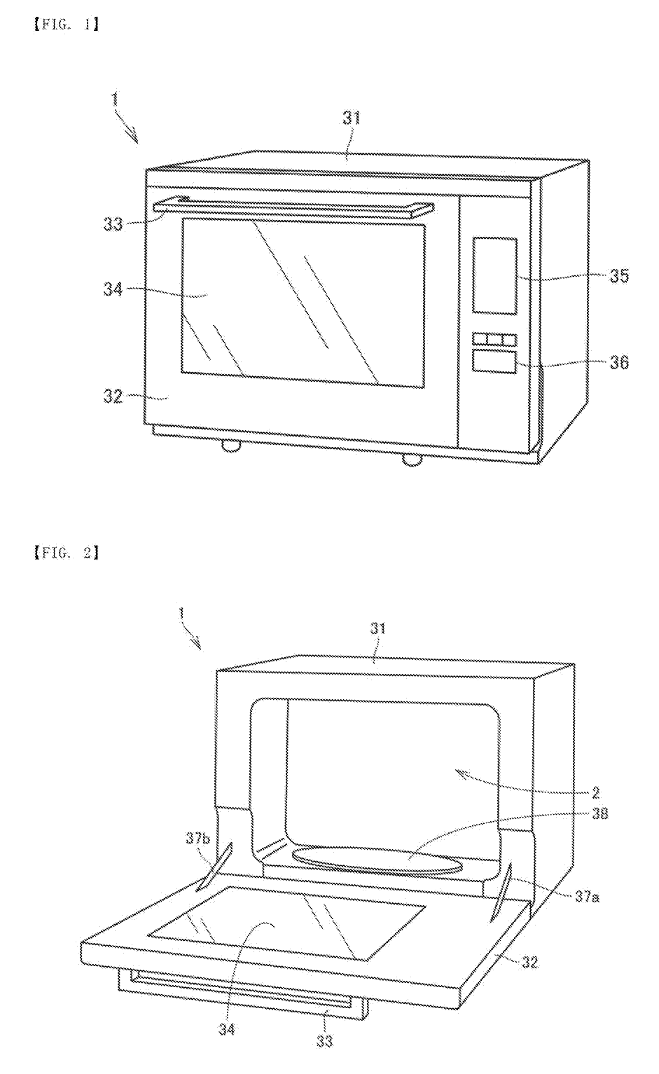

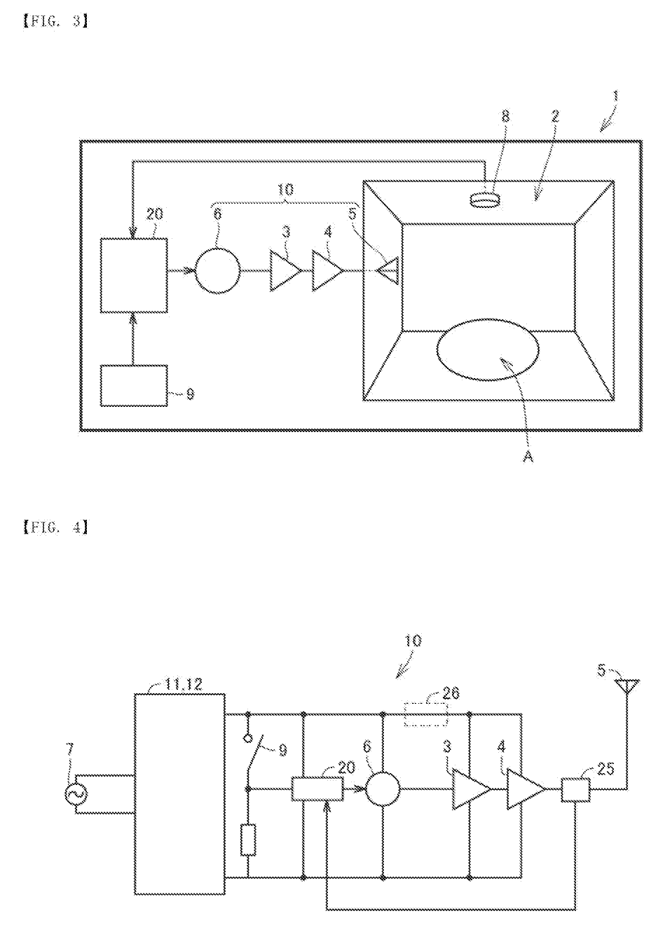

The overall configuration of a heating cooker 1 according to First Embodiment is described first. FIG. 1 is a perspective view showing the appearance of the heating cooker according to the embodiment of the present invention. FIG. 2 is a perspective view showing the heating cooker of the present embodiment with an insulating door open.

As shown in FIGS. 1 and 2, the heating cooker 1 according to the embodiment of the present invention has a box-shaped body 31 having a front opening. The box-shaped body 31 includes a heating compartment (heating chamber) 2 in which an item to be heated is put through the opening. The front opening of the box-shaped body 31 is at an end portion on the front side of the heating compartment 2.

The heating compartment 2 is surrounded by a ceiling, a bottom surface, and left and right side surfaces. A tray 38 is disposed in the heating compartment 2. Specifically, the tray 38 is disposed on the bottom surface of the heating compartment 2. An item to be heated is put on the tray 38.

An antenna 5 (see FIG. 3) for sending high-frequency waves that heat the material cooked in the heating compartment 2 Is disposed on a side (side surface) of the box-shaped body 31.

An insulating door (hereinafter, simply “door”) 32 that opens and closes the opening is provided on the front side of the box-shaped body 31. That, is, the door 32 opens and closes the heating compartment 2. In the present embodiment, as shown in FIG. 2, the door 32 is a bottom-hinged door attached to a bottom portion on the front side of the box-shaped body. However, the present invention is not limited to this embodiment, and the door may use a side-hinged open/close mechanism, instead of a top- or bottom-hinged open/close mechanism.

As described above, the heating cooker 1 of the present embodiment is provided with an open/close mechanism that openably supports the door 32 on the box-shaped body 31. The open/close mechanism includes left and right door arms 37a and 37b, among others.

A door switch 9 (see FIG. 3) for detecting whether the door is open or closed is provided for the door 32 and the box-shaped body 31, though not illustrated in FIGS. 1 and 2. The door switch 9 (open/close detection unit) has two switch units, one for the door 32, and one for the box-shaped body 31. The door switch 9 switches itself between ON and OFF depending on whether the switch units are in contact with or not in contact with each other. The door switch 9 may be configured as, for example, a contact sensor. In this case. the door 32 and the box-shaped body 31 are each provided with a sensor unit, and the door switch 9 switches itself between ON and OFF depending on whether the distance between the sensor units is longer or shorter than a predetermined distance.

A handle 33 is provided at an upper front portion of the door 32. The front face of the door 32 has a display section 35 for displaying information such as a temperature inside the heating compartment 2, and cooking conditions. The front face of the door 32 also has a control 36 that allows a user of the heating cooker 1 to input cooking conditions. The display section 35 and the control 36 are connected to a control unit 20 (see FIG. 3), a control means disposed in the box-shaped body 31.

The door 32 has a window portion 34 that provides visual access to inside of the heating compartment 2 from outside of the heating cooker 1. The window portion 34 is formed of a heat-insulating transparent material. A shield member for preventing leakage of electromagnetic waves to outside is installed on the back (inner side) of the window portion 34.

The configuration of the heating cooker described above is an example of the present invention. Accordingly, the heating cooker of the present invention is not limited to the foregoing configuration.

### Inner Configuration of Heating Cooker

The inner configuration of the heating cooker 1 according to the present embodiment is described below, with reference to FIG. 3. The heating cooker 1 applies high-frequency-power electromagnetic radiation to an item to be heated A, such as food, to cook it by heating or thawing, for example. As shown in FIG. 3, the main components of the heating cooker 1 include the heating compartment 2, a first semiconductor amplifier (amplifier circuit) 3, a second semiconductor amplifier (amplifier circuit) 4, the antenna 5, a high-frequency oscillation circuit 6, a temperature sensor 8, the door switch 9, and the control unit 20.

The heating compartment 2 is formed as a metal cabinet. An item to be heated A, such as food, is placed inside the heating compartment 2. The antenna 5 of a high-frequency power supply 10 (described later) emits high-frequency electromagnetic radiation to heat the item to be heated A in the heating compartment 2.

The first semiconductor amplifier 3, the second semiconductor amplifier 4, the antenna 5, and the high-frequency oscillation circuit 6 constitute the high-frequency power supply 10. Specifically, the high-frequency oscillation circuit 6 modulates the oscillating frequency of a high-frequency signal to a 2.4 GHz to 2.5 GHz frequency suited for the size and the properties of the item to be heated A. The first semiconductor amplifier 3 and the second semiconductor amplifier 4 amplify the high-frequency signal sent from the high-frequency oscillation circuit 6. The high-frequency power obtained from the high-frequency signal amplified by the amplifier circuits is sent into the heating compartment 2 from the antenna 5.

In the present embodiment, two semiconductor amplifiers are provided, and a high-frequency signal is amplified stepwise by these semiconductor amplifiers. However, the present invention is not limited to the embodiment with two semiconductor amplifiers. Another form of the present invention may have a configuration with only one semiconductor amplifier, or three or more semiconductor amplifiers.

The temperature sensor 8 is disposed on, for example, the ceiling of the heating compartment 2. The temperature sensor 8 monitors the temperature of the item to be heated A. The control unit 20 (see FIG. 3) is connected to components of the heating cooker 1 to control these components. For example, the control unit 20 controls procedures such as adjustments of high-frequency power from the high-frequency oscillation circuit 6, and termination of heating, using the temperature information monitored by the temperature sensor

As described above, the door switch 9 has two switch units, one for the door 32, and one for the box-shaped body 31. The door switch 9 detects whether the door 32 is in an open state or a closed state. The door switch 9 is connected to the control unit 20. From the door switch 9, the control unit 20 receives a detection result concerning whether the door 32 is open or closed. The control unit 20 controls the high-frequency oscillation circuit 6 and other components using the information from the door switch 9 concerning whether the door 32 is open or closed. For example, in the present embodiment, the control unit 20 stops the high-frequency oscillation circuit 6 when the door 32 is opened.

### Configuration of High-Frequency Power Supply

The inner configuration of the high-frequency power supply 10 of the heating cooker 1 is described below, with reference to FIGS. 4 and 5. FIG. 4 shows a circuit structure of the high-frequency power supply 10. FIG. 5 shows a circuit structure of a part of the high-frequency power supply 10 (specifically, a full-wave rectification circuit 11, and a switching converter 12).

The main components of the high-frequency power supply 10 include the first semiconductor amplifier 3, the second semiconductor amplifier 4, the antenna 5, the high-frequency oscillation circuit 6, a commercial power supply (alternating-current (AC) power supply) 7, the full-wave rectification circuit 11, the switching converter 12, and a power meter 25. The door switch 9 and a DC relay 26 are among the components that are integrated in the circuit forming the high-frequency power supply 10. The control unit 20 is also connected to the circuit forming the high-frequency power supply 10.

The commercial power supply 7 supplies AC power. The full-wave rectification circuit 11 rectifies a single-phase AC voltage from the commercial power supply 7, and supplies power to the switching converter 12.

The switching converter 12 is a flyback converter, and follows the voltage of the commercial power supply 7, in order to improve the input power factor of the commercial power supply 7. Aside from a flyback converter, the switching converter 12 may be, for example, a DC-DC converter.

As shown in FIG. 5, the switching converter 12 is configured from a primary smoothing capacitor 13, a power supply controller 14, a transformer (power converter) 15, an FET (field-effect transistor) 16, and a Snubber capacitor 17, among others. The switching converter 12 also includes other components, including a diode 18 and a secondary electrolytic capacitor 19, on the secondary side of the transformer (power converter) 15.

The primary smoothing capacitor 13 and the secondary electrolytic capacitor 19 absorb the switching frequency component. The secondary electrolytic capacitor 19 is, for example, a large-capacity electrolytic capacitor. In this way, the alternating current from the commercial power supply 7 can be converted into DC voltage, and supplied to the power supply of the semiconductor amplifiers 3 and 4 while improving the power factor of the input voltage.

The switching converter 12 controls ON/OFF of the FET 16 with the power supply controller 14, allowing the current of the commercial power supply 7 to follow the voltage of the commercial power supply 7. In this way, the input power factor of the commercial power supply 7 can improve.

The high-frequency oscillation circuit 6, the first semiconductor amplifier 3, the second semiconductor amplifier 4, the power meter 25, and the antenna 5 are among the components on the following stage of the switching converter 12 connected to these components.

The power meter 25 is disposed between the second semiconductor amplifier 4 and the antenna 5. The power meter 25 measures the power level of the high-frequency power supplied to the antenna 5. Information of the power level measured by the power meter 25 is sent to the control unit 20.

The DC relay 26 is disposed in a line on which the DC voltage converted in the switching converter 12 is supplied to the power supply of the semiconductor amplifiers 3 and 4. The DC relay 26 switches itself ON and OFF under the control of the control unit 20. Power is supplied to the semiconductor amplifiers 3 and 4 when the DC relay 26 is ON. Power supply to the semiconductor amplifiers 3 and 4 is stopped when the DC relay 26 is OFF.

The control unit 20 is connected to components of the high-frequency power supply 10 to control these components. The control unit 20 is also connected to the door switch 9. Accordingly, the ON/OFF signal of the door switch 9 is sent to the control unit 20.

### High-Frequency Power Supply Control Method in Opening and Closing Door

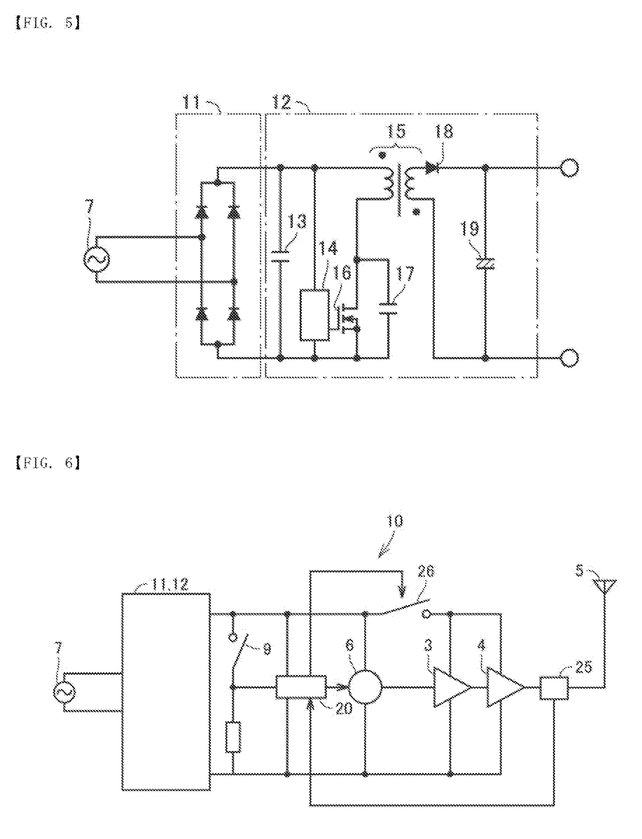

The following describes how the high-frequency power supply 10 is controlled when the door 32 is opened and closed, with reference to FIGS. 4 and 6.

In response to a user opening the door 32 of the heating compartment 2, the door switch 9 detects that the door 32 is in an open state. This information is sent to the control unit 20. Upon receiving the information that the door 32 is open, the control unit 20 stops the high-frequency oscillation circuit 6 (see FIG. 4). That is, the control unit 20 stops the high-frequency oscillation circuit 6 from sending a high-frequency signal. In the present embodiment, the control unit 20 stops sending of a high-frequency signal by controlling the oscillatory ON/OFF terminal of the high-frequency oscillation circuit 6.

The semiconductor amplifiers 3 and 4 stop sending high-frequency output as soon as the high-frequency signal is stopped. This results in lower current being consumed by the semiconductor amplifiers 3 and 4. In this way, the high-frequency radiation into the heating compartment 2 can be cut off with ease while reducing arc generation in the DC relay 26 and other switches.

The control unit 20 opens the DC relay 26 after confirming that the power level in power meter 25 has decreased to a sufficiently small level (see FIG. 6). In this way, the DC relay 26 can have a reduced load.

In response to a user closing the door 32, the door switch 9 detects that the door 32 is in a closed state. This information is sent to the control unit 20. Upon receiving the information that the door 32 is closed, the control unit 20 closes the DC relay 26 after ensuring the safety of surroundings. In response, the high-frequency oscillation circuit 6 may immediately start sending a high-frequency signal, or may send a high-frequency signal after receiving a further instruction from the control unit 20.

As described above, the heating cooker 1 according to the present embodiment detects whether the door 32 is open or closed, and stops the high-frequency signal from the high-frequency oscillation circuit 6 while the door 32 is in an open state. In this way, high-frequency output can be safely cut off in a coordinated fashion with opening of the door. Particularly, in a high-frequency heating device equipped with the DC-operated semiconductor amplifiers 3 and 4 as in the present embodiment, high-frequency output can be immediately stopped when the door 32 is opened, without the DC relay 26 being affected by an arc. The foregoing configuration is preferred in this respect.

With the foregoing configuration, the DC relay 26 of the semiconductor amplifiers 3 and 4 requiring large current can be disposed in the vicinity of the circuit of the high-frequency power supply 10, simply by routing a signal line for the door open/close mechanism to the door 32 in the box-shaped body 31. Because there is no urgent need to route a large-current DC line inside the box-shaped body 31, the box-shaped body can be more freely designed.

First Embodiment described an example of a heating cooker that generates electromagnetic waves of a UHF frequency range of 2.4 GHz to 2.5 GHz. However, in another form of the present invention, the heating cooker may generate electromagnetic waves in a UHF frequency range of 0.3 GHz to 3 GHz.

### Variation of First Embodiment

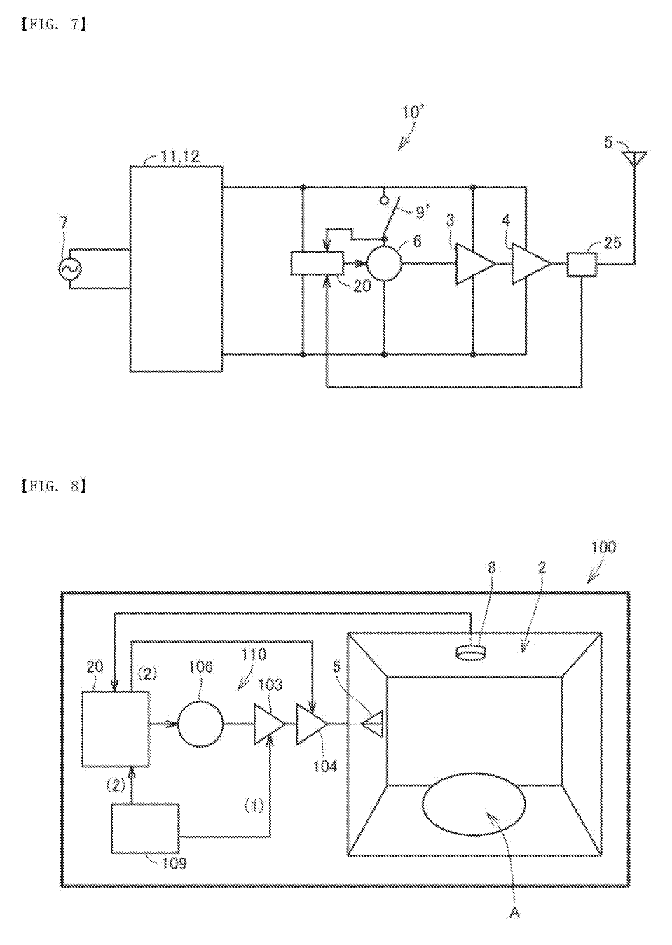

The following describes a variation of the high-frequency power supply 10 of First Embodiment. FIG. 1 shows a circuit structure of a high-frequency power supply 10′ according to a variation of First Embodiment. As shown in FIG. 7, the high-frequency power supply 10′ according to a variation of First Embodiment differs from First Embodiment in the position of a door switch 9′ (switch). Other configurations may be the same as those described in First Embodiment.

In the high-frequency power supply 10′, the door switch 9′ is disposed in a line on which the DC voltage converted in the switching converter 12 is supplied to the power supply of the high-frequency oscillation circuit 6. Accordingly, power supply to the high-frequency oscillation circuit 6 is stopped when the door switch 9′ is switched OFF (i.e., when the door 32 is opened). Power is supplied to the high-frequency oscillation circuit 6 when the door switch 9′ is switched ON (when the door 32 is closed).

With this configuration, the high-frequency oscillation circuit 6 can start and stop working in a coordinated fashion with ON/OFF (close/open) of the door switch 9′, without involving the control unit 20. That is, in this variation, the door switch 9′ (open/close detection unit) that detects whether the door 32 is open or closed can serve as a switch that stops the high-frequency oscillation circuit 6 when the door 32 is opened.

### Second Embodiment

Second Embodiment of the present invention is described below. First Embodiment described a configuration in which the high-frequency oscillation circuit stops working when the door of the heating compartment is opened. Second Embodiment describes a configuration in which power supply to the first semiconductor amplifier is stopped when the door of the heating compartment is opened.

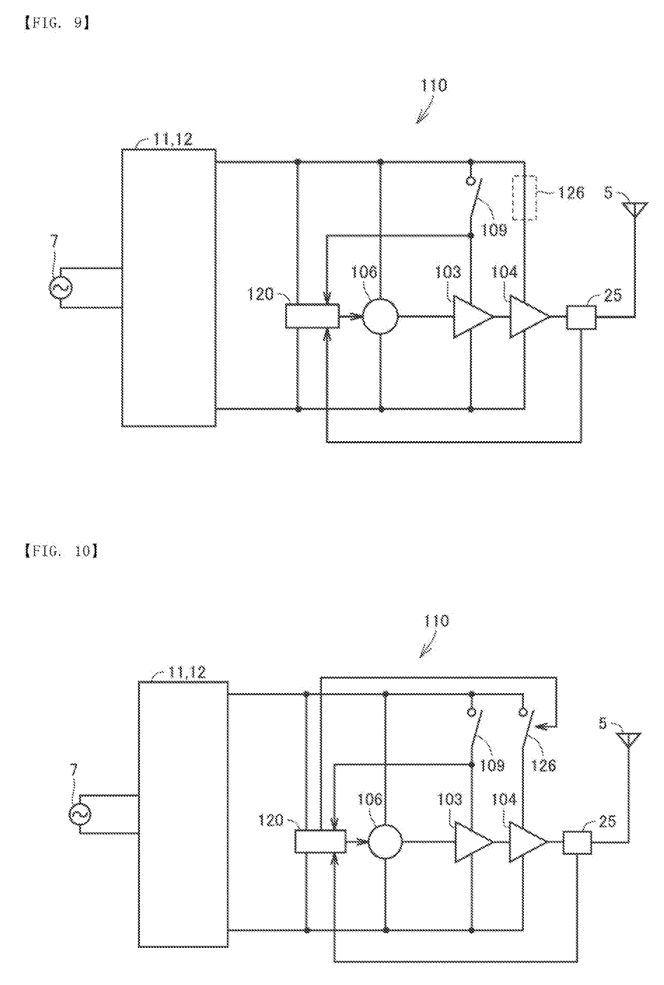

FIG. 8 shows a microwave heating cooker (hereinafter, simply “heating cooker”) 100 according to Second Embodiment. The heating cooker 100 is an example of a dielectric heating apparatus according to an aspect of the present invention. The heating cooker 100 has the same basic configuration as the heating cooker 1 according to First Embodiment (see FIG. 1). Accordingly, in the heating cooker 100, the same reference numerals will be used for elements having the same structures and functions described for the heating cooker 1, and descriptions of such members are omitted.

As shown in FIG. 8, the main components of the heating cooker 100 include a heating compartment 2, a first semiconductor amplifier (first-stage semiconductor amplifier) 103, a second semiconductor amplifier (second-stage semiconductor amplifier) 104, an antenna 5, a high-frequency oscillation circuit 106, a temperature sensor 8, a door switch 109, and a control unit 20. The first semiconductor amplifier 103, the second semiconductor amplifier 104, the antenna 5, and the high-frequency oscillation circuit 106 constitute a high-frequency power supply 110.

FIG. 9 shows a circuit structure of the high-frequency power supply 110. The main components of the high-frequency power supply 110 include the first semiconductor amplifier 103, the second semiconductor amplifier 104, the antenna 5, the high-frequency oscillation circuit 106, a commercial power supply (alternating-current power supply) 7, a full-wave rectification circuit 11, a switching converter 12, and a power meter 25. The door switch 109 (first switch) and a DC relay 126 (second switch) are among the components that are integrated in the circuit forming the high-frequency power supply 110. The control unit 120 is also connected to the circuit forming the high-frequency power supply 110.

The first semiconductor amplifier 103 (corresponding to the first semiconductor amplifier 3), the second semiconductor amplifier 104 (corresponding to the second semiconductor amplifier 4), the antenna 5, the high-frequency oscillation circuit 106 (corresponding to the high-frequency oscillation circuit 6), the commercial power supply (alternating-current power supply) 7, the full-wave rectification circuit 11, the switching converter 12, and the power meter 25 may have essentially the same configurations described in First Embodiment.

The door switch 109 (first switch) has two switch units, one for the door 32, and one for the box-shaped body 31. The door switch 109 detects whether the door 32 is in an open state or a closed state. The door switch 109 is connected to the control unit 120. In the present embodiment, the door switch 109 is disposed in a line on which the DC voltage converted in the switching converter 12 is supplied to the power supply of the first-stage semiconductor amplifier 103. In this way, power supply to the semiconductor amplifier 103 is stopped when the door switch 109 opens. Power is supplied to the semiconductor amplifier 103 when the door switch 109 closes. That is, power is supplied to the semiconductor amplifier 103 in a coordinated fashion with opening and closing of the door 32.

The DC relay 126 (second switch) is disposed in a line on which the DC voltage converted in the switching converter 12 is supplied to the power supply of the second-stage semiconductor amplifier 104. The DC relay 126 switches itself ON and OFF under the control of the control unit 120. Power is supplied to the semiconductor amplifier 104 when the DC relay 126 is ON. Power supply to the semiconductor amplifier 104 is stopped when the DC relay 126 is OFF.

### High-Frequency Power Supply Control Method in Opening and Closing Door

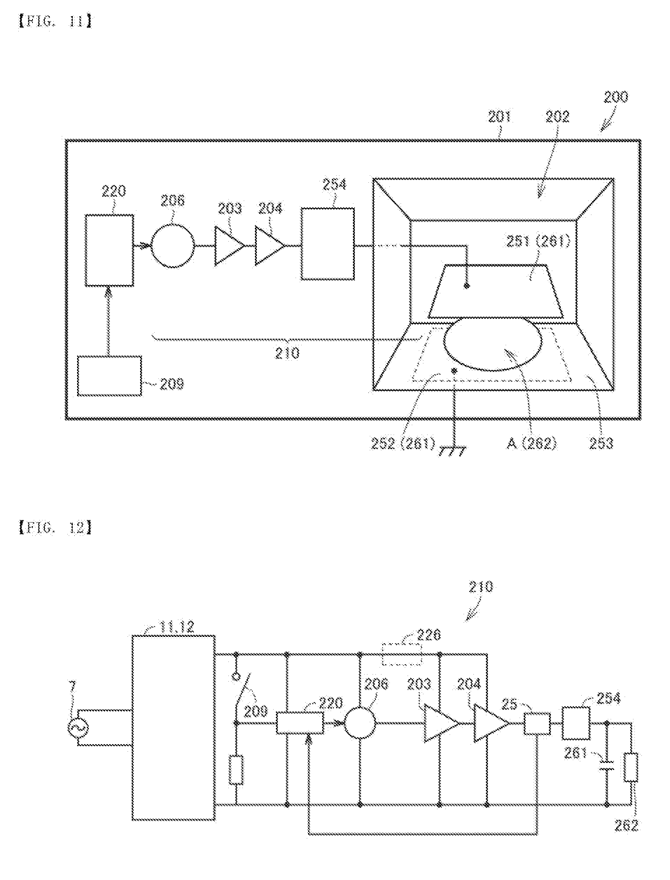

The following describes how the high-frequency power supply 110 is controlled in opening and closing the door 32, with reference to FIGS. 9 and 10.

The door switch 109 opens (OFF) in response to a user opening the door 32 of the heating compartment 2. As described above, the door switch 109 switches ON and OFF the power supplied to the first-stage semiconductor amplifier 103, and, accordingly, the DC voltage supply to the semiconductor amplifier 103 is stopped when the door switch 109 opens (see FIG. 8, (1), and FIG. 9). Because the first-stage semiconductor amplifier 103 is consuming relatively smaller current (for example, about 0.1 A), the power supply can be cut off with ease.

Information from the door switch 109 detecting that the door 32 is open is sent to the control unit 120 (see FIG. 8, (2)). The control unit 120 opens the DC relay 126 (OFF) upon receiving the information that the door 32 is open. As described above, the DC relay 126 switches ON and OFF the power supply to the second-stage semiconductor amplifier 104, and, accordingly, the DC voltage supply to the semiconductor amplifier 104 is stopped when the DC relay 126 opens (see FIG. 8, (2), and FIG. 10).

The first-stage semiconductor amplifier 103 stops sending high-frequency output to the second-stage semiconductor amplifier 104 as soon as the DC voltage supply to the first-stage semiconductor amplifier 103 is stopped. Accordingly, there is no high-frequency output from the second-stage semiconductor amplifier 104, and the consumed current in the second-stage semiconductor amplifier 104 is small. In this way, the high-frequency radiation into the heating compartment 2 can be cut off with ease while reducing arc generation in the DC relay 126.

In response to a user closing the door 32, the door switch 109 closes (ON), allowing power to be supplied to the first-stage semiconductor amplifier 103. The information indicating that the door 32 is in a closed state is sent to the control unit 120. Upon receiving the information that the door 32 is closed, the control unit 120 preferably checks the safety of surroundings, before closing the DC relay 126. After ensuring the safety of surroundings, the control unit 120 preferably starts supplying power to the second-stage semiconductor amplifier 104 by closing the DC relay 126 (ON).

As described above, the heating cooker 100 according to the present embodiment opens and closes only the line supplying DC voltage to the first-stage semiconductor amplifier 103 consuming relatively smaller current, using the door switch 109 (mechanical switch) linked to the door 32. In this way, the high-frequency radiation output into the heating compartment 2 can be stopped both safely and instantaneously in a coordinated fashion with opening of the door 32.

Specifically, in a high-frequency heating device equipped with the DC-operated semiconductor amplifiers 103 and 104 as in the present embodiment, the high-frequency output can be immediately stopped when the door 32 is opened, without the DC relay 126 being affected by an arc. The foregoing configuration is preferred in this respect.

With the foregoing configuration, the DC relay 26 of the second-stage semiconductor amplifier 104 requiring larger current can be disposed in the vicinity of the circuit of the high-frequency power supply 110. Because there is no urgent need to route a large-current DC line inside the box-shaped body 31, the box-shaped body can be more freely designed.

### Third Embodiment

Third Embodiment of the present invention is described below. The foregoing First and Second Embodiments described microwave heating cookers as examples of a dielectric heating apparatus according to an aspect of the present invention. Third Embodiment describes a dielectric heating and thawing device as another example of a dielectric heating apparatus according to an aspect of the present invention.

The dielectric heating and thawing device 200 (hereinafter, referred to simply as “defroster”) according to the present embodiment heats or thaws an item to be heated, such as food, using electromagnetic waves of a VHF frequency range of 30 MHz to 300 MHz (specifically, a frequency of 40.68 MHz). However, the electromagnetic frequency used in the defroster of the present embodiment is not limited to this. The defroster of the present embodiment may use, for example, electromagnetic waves of an HF frequency range of 3 MHz to 30 MHz.

### Overall Configuration of Dielectric Heating and Thawing Device

The overall configuration of the defroster 200 according to the present embodiment is described below, with reference to FIG. 11. The defroster 200 exposes an item to be heated (item to be thawed) A, such as food, to a high-frequency electric field to cook the item by heating or thawing. As shown in FIG. 11, the main components of the defroster 200 include a cabinet (box-shaped body) 201, a heating compartment (heating chamber) 202, a door switch (open/close detection unit) 209, a control unit 220, and a high-frequency power supply 210.

The high-frequency power supply 210 includes a first semiconductor amplifier (amplifier circuit) 203, a second semiconductor amplifier (amplifier circuit) 204, a high-frequency oscillation circuit 206, an upper electrode (electrode) 251, a lower electrode (electrode) 252, and a matching circuit 251, among others.

The cabinet 201 defines the outer shape of the defroster 200. The heating compartment 202 is formed as a metal cabinet. An item to be heated A, such as food, is placed inside the heating compartment 202. The upper electrode 251, the lower electrode 252, and a ceramic plate 253 are disposed in the heating compartment 202, among others. The lower electrode 252 is disposed underneath the ceramic plate 253. The lower electrode 252 is grounded, and the potential is zero.

The high-frequency power supply 210 creates a high-frequency electric field between the upper electrode 251 and the lower electrode 252, as will be described later. The item to be heated A is placed between the upper electrode 251 and the lower electrode 252. In this state, a high-frequency high voltage is applied across the electrodes 251 and 252f and the item to be heated A, which is a dielectric, is heated from both sides by dielectric heating. The item to be heated A is heated or thawed as a result of dielectric loss.

The control unit 220 is connected to components of the defroster 200, and controls these components. Examples of the control procedures by the control unit 220 include adjustments of high-frequency power, and termination of heating.

The door switch 209 has two switch units, one for the door (not illustrated) mounted to the heating compartment 202, and one for the heating compartment 202. The door switch 209 detects whether the door is in an open state or a closed state. The door switch 209 is connected to the control unit 220. Information from the door switch 209 detecting that the door is open or closed is sent to the control unit 220. The control unit 220 controls the high-frequency oscillation circuit 206 and other components by using the information from the door switch 209 detecting that the door is open or closed. For example, in the present embodiment, the control unit 220 stops the high-frequency oscillation circuit 206 when the door is opened.

### Configuration of High-Frequency Power Supply

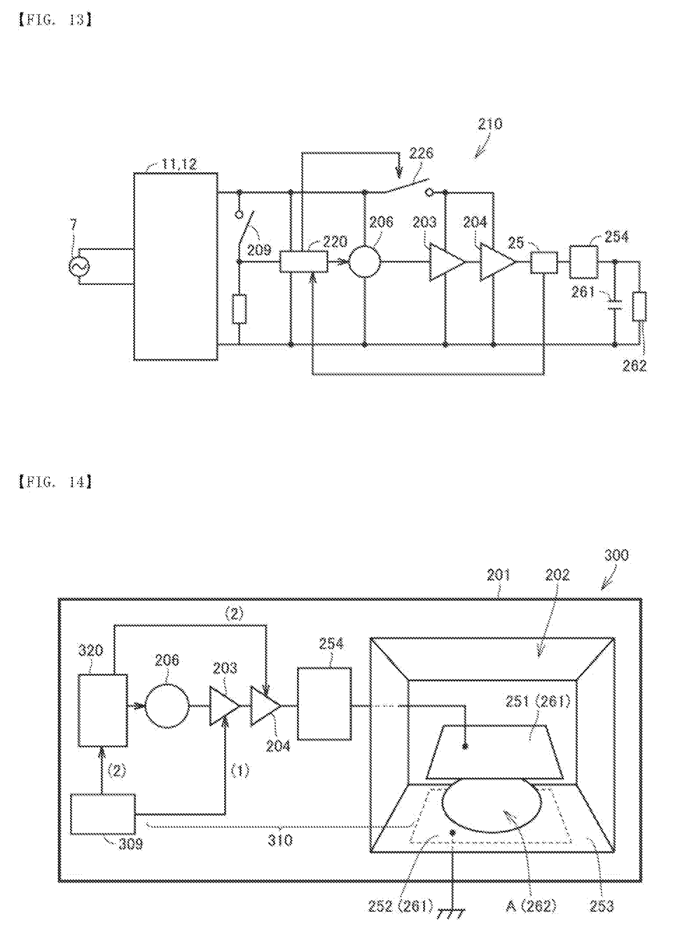

The inner configuration of the high-frequency power supply 210 of the defroster 200 is described below, with reference to FIG. 12. FIG. 12 shows a circuit structure of the high-frequency power supply 210. The main components of the high-frequency power supply 210 include the first semiconductor amplifier 203, the second semiconductor amplifier 204, the high-frequency oscillation circuit 206, a commercial power supply (alternating-current power supply) 7, a full-wave rectification circuit 11, a switching converter 12, the matching circuit 254, and a power meter 25.

The high-frequency power supply 210 generates a high-frequency signal of, for example, 40.68 MHz in the high-frequency oscillation circuit 206. The high-frequency signal is amplified by the first semiconductor amplifier 203 and the second semiconductor amplifier 204, and subjected to impedance matching in the matching circuit 254. The high-frequency power obtained from the high-frequency signal is applied to an equivalent capacitor 261 configured from the upper electrode 251 and the lower electrode 252, and to an equivalent resistor 262 configured from the item to be heated A. This creates a high-frequency electric field between the upper electrode 251 and the lower electrode 252, and the item to be heated A between the upper electrode 251 and the lower electrode 252 is exposed to high-frequency power.

The commercial power supply (alternating-current power supply) 7, the full-wave rectification circuit 11, the switching converter 12, and the power meter 25 in the high-frequency power supply 210 may have the same configurations as those described in First Embodiment. However, because the frequency band is different from that used in First Embodiment, the inner configuration is different from First Embodiment for the high-frequency oscillation circuit 206, the first semiconductor amplifier 203, and the second semiconductor amplifier 204. In the present embodiment, the high-frequency oscillation circuit 206, the first semiconductor amplifier 203, and the second semiconductor amplifier 204 are configured to be suited for the VHF band frequency.

The door switch 209 and a DC relay 226 are among the components integrated in the circuit forming the high-frequency power supply 210. The control unit 220 is also connected to the circuit forming the high-frequency power supply 210.

### High-Frequency Power Supply Control Method in Opening and Closing Door

The following describes how the high-frequency power supply 210 is controlled in opening and closing the door of the heating compartment 202, with reference to FIGS. 12 and 13.

In response to a user opening the door of the heating compartment 202, the door switch 209 detects that the door is in an open state. This information is sent to the control unit 220. Upon receiving the information that the door of the heating compartment 202 is open, the control unit 220 stops the high-frequency oscillation circuit 206 (see FIG. 12), as in First Embodiment.

The semiconductor amplifiers 203 and 204 stop sending high-frequency output as soon as the high-frequency signal is stopped. This results in smaller current being consumed by the semiconductor amplifiers 203 and 204. In this way, the high-frequency radiation into the heating compartment 202 can be cut off with ease while reducing arc generation in the DC relay 226.

The control unit 220 opens the DC relay 226 after confirming that the power level in the power meter 25 has decreased to a sufficiently small level (see FIG. 13). In this way, the DC relay 226 can have a reduced load.

In response to a user closing the door of the heating compartment 202, the door switch 209 detects that the door is in a closed state. This information is sent to the control unit 220. Upon receiving the information that the door is closed, the control unit 220 closes the DC relay 226, after ensuring the safety of surroundings, as in First Embodiment. In response, the high-frequency oscillation circuit 206 may immediately start sending a high-frequency signal, or may send a high-frequency signal after receiving a further instruction from the control unit 220.

As described above, the defroster 200 according to the present embodiment detects whether the door of the heating compartment 202 is open or closed, and stops the high-frequency signal from the high-frequency oscillation circuit 206 while the door is in an open state. In this way, high-frequency output can be safely cut off in a coordinated fashion with opening of the door.

### Fourth Embodiment

Fourth Embodiment of the present invention is described below. Third Embodiment described a configuration in which the high-frequency oscillation circuit stops working when the door of the heating compartment is opened. Fourth Embodiment describes a configuration in which power supply to the first semiconductor amplifier is stopped when the door of the heating compartment is opened.

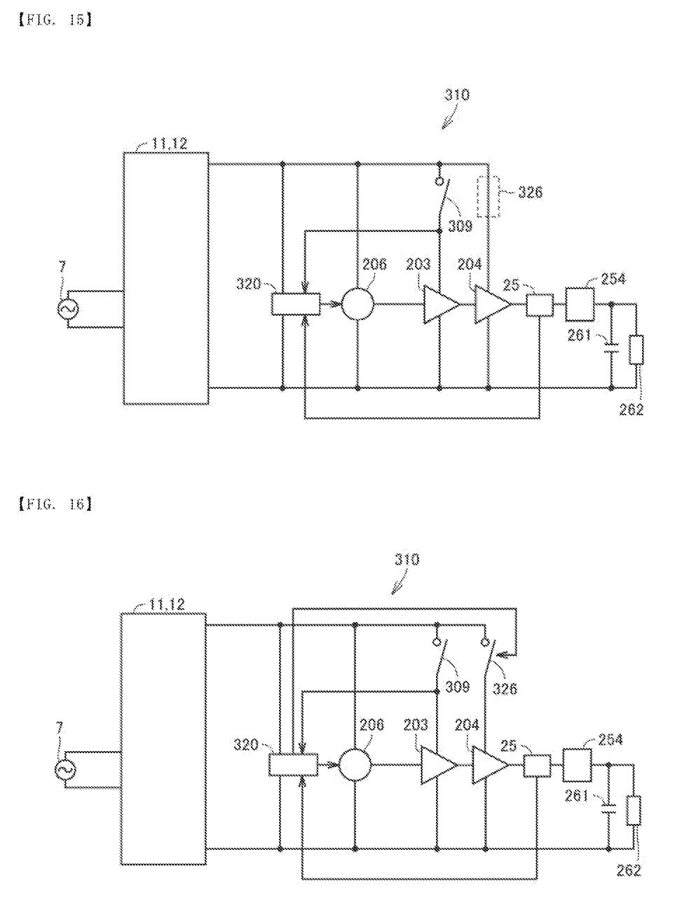

FIG. 14 shows a dielectric heating and thawing device 300 (hereinafter, referred to simply as “defroster”) according to Fourth Embodiment. The defroster 300 is an example of a dielectric heating apparatus according to an aspect of the present invention. The defroster 300 has the same basic configuration as the defroster 200 according to Third Embodiment. Accordingly, in the defroster 300, the same reference numerals will be used for elements having the same structures and functions described for the defroster 200, and descriptions of such members are omitted.

As shown in FIG. 14, the main components of the defroster 300 include a cabinet (box-shaped body) 201, a heating compartment (heating chamber) 202, a door switch (open/close detection unit) 309, a control 320, and a high-frequency power supply 310.

The high-frequency power supply 310 includes a first semiconductor amplifier (first-stage semiconductor amplifier) 203, a second semiconductor amplifier (second-stage semiconductor amplifier) 204, a high-frequency oscillation circuit 206, an upper electrode (electrode) 251, a lower electrode (electrode) 252, and a matching circuit 254, among others.

An item to be heated A, such as food, is placed inside the heating compartment 202. The upper electrode 251, the lower electrode 252, and a ceramic plate 253 are disposed in the heating compartment 202, among others. The lower electrode 252 is disposed underneath the ceramic plate 253. The lower electrode 252 is grounded, and the potential is zero.

The FIG. 15 shows a circuit structure of the high-frequency power supply 310. The main components of the high-frequency power supply 310 includes the first semiconductor amplifier 203, the second semiconductor amplifier 204, the high-frequency oscillation circuit 206, a commercial power supply (alternating-current power supply) 7, a full-wave rectification circuit 11, a switching converter 12, the matching circuit 254, and a power meter 25. The door switch 309 (first switch) and a DC relay 326 (second switch) are among the components integrated in the circuit forming the high-frequency power supply 310. The control unit 320 is also connected to the circuit forming the high-frequency power supply 310.

The high-frequency power supply 310 generates a high-frequency signal of, for example, 40.68 MHz in the high-frequency oscillation circuit 206. The high-frequency signal is amplified by the first semiconductor amplifier 203 and the second semiconductor amplifier 204, and subjected to impedance matching in the matching circuit 254. The high-frequency power obtained from the high-frequency signal is applied to an equivalent capacitor 261 configured from the upper electrode 251 and the lower electrode 252, and to an equivalent resistor 262 configured from the item to be heated A. This creates a high-frequency electric field between the upper electrode 251 and the lower electrode 252, and the item to be heated A between the upper electrode 251 and the lower electrode 252 is exposed to high-frequency power.

The first semiconductor amplifier 203, the second semiconductor amplifier 204, the high-frequency oscillation circuit 206, the commercial power supply (alternating-current power supply) 7, the full-wave rectification circuit 11, the switching converter 12, the power meter 25, the matching circuit 254, and the equivalent capacitor 261 (the upper electrode 251 and the lower electrode 252) may have essentially the same configurations as those described in Third Embodiment.

The door switch 309 is disposed in a line on which the DC voltage converted in the switching converter 12 is supplied to the power supply of the first-stage semiconductor amplifier 203. The DC relay 326 is disposed in a line on which the DC voltage converted in the switching converter 12 is supplied to the power supply of the second-stage semiconductor amplifier 204. The door switch 309 (first switch) and the DC relay 326 (second switch) may have essentially the same configurations as the door switch 109 and the DC relay 126 of Second Embodiment.

### High-Frequency Power Supply Control Method in Opening and Closing Door

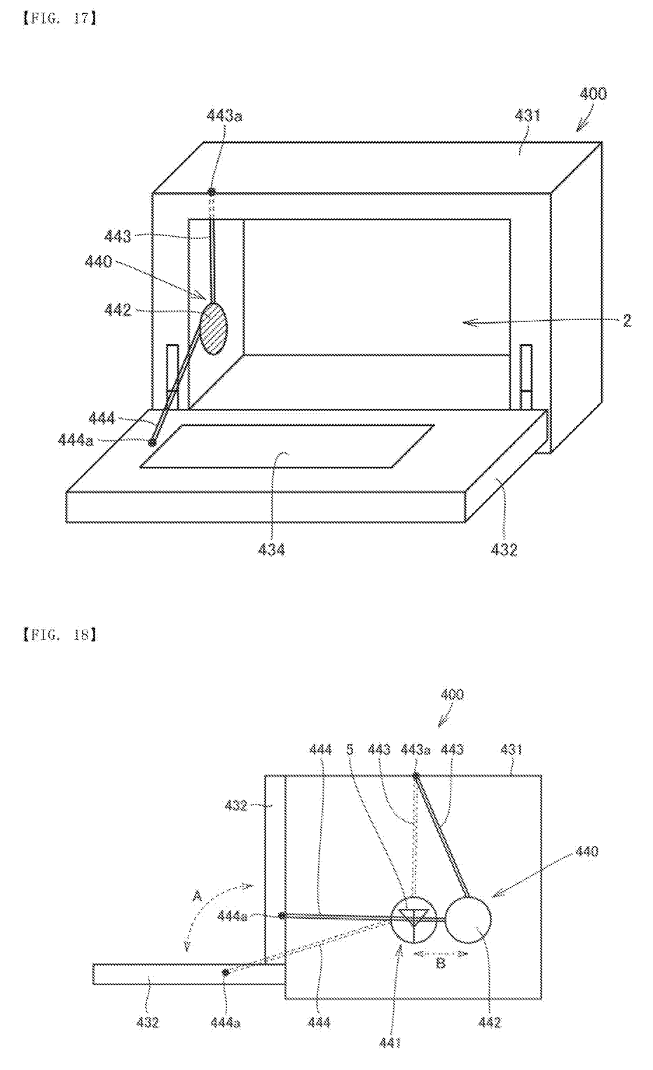

The following describes how the high-frequency power supply 310 is controlled in opening and closing the door of the heating compartment 202, with reference to FIGS. 15 and 16.

The door switch 309 opens (OFF) in response to a user opening the door of the heating compartment 202. As described above, the door switch 309 switches ON and OFF the power supplied to the first-stage semiconductor amplifier 203, and, accordingly, the DC voltage supply to the semiconductor amplifier 203 is stopped when the door switch 309 opens (see FIG. 14, (1), and FIG. 15).

Information from the door switch 309 detecting that the door of the heating compartment 202 is open is sent to the control unit 320 (see FIG. 14, (2)). The control 320 opens (OFF) the DC relay 326 upon receiving the information that the door is open. As described above, the DC relay 32 6 switches ON and OFF the power supplied to the second-stage semiconductor amplifier 204, and, accordingly, the DC voltage supply to the semiconductor amplifier 204 is stopped when the DC relay 326 opens (see FIG. 14, (2), and FIG. 16).

The first-stage semiconductor amplifier 203 stops sending high-frequency output to the second-stage semiconductor amplifier 104 as soon as the DC voltage supply to the first-stage semiconductor amplifier 203 is stopped. Accordingly, there is no high-frequency output from the second-stage semiconductor amplifier 204, and the consumed current in the second-stage semiconductor amplifier 204 is small. In this way, the high-frequency radiation into the heating compartment 202 can be cut off with ease while reducing arc generation in the DC relay 326.

In response to a user closing the door of the heating compartment 202, the door switch 309 closes (ON), allowing power to be supplied to the first-stage semiconductor amplifier 203. The information indicating that the door is in a closed state is sent to the control unit 320. Upon receiving the information that the door is closed, the control unit 320 preferably checks the safety of surroundings, before closing the DC relay 326. After ensuring the safety of surroundings, the control unit 320 preferably starts supplying power to the second-stage semiconductor amplifier 204 by closing the DC relay 326 (ON).

As described above, the defroster 300 according to the present embodiment opens and closes only the line supplying DC voltage to the first-stage semiconductor amplifier 203 consuming relatively smaller current, using the door switch 309 (mechanical switch) linked to the door of the heating compartment 202. In this way, the high-frequency radiation output into the heating compartment 202 can be stopped both safely and instantaneously in a coordinated fashion with opening of the door of the heating compartment 202.

### Fifth Embodiment

Fifth Embodiment of the present invention is described below. First Embodiment described a configuration in which the high-frequency oscillation circuit stops working when the door of the heating compartment is opened. Fifth Embodiment describes a microwave heating cooker of a configuration in which a high-frequency signal is sent into the heating compartment through an aperture provided in the heating compartment, and in which the aperture is physically blocked when the door of the heating compartment is opened.

FIG. 17 schematically shows a configuration inside the heating compartment 2 of a microwave heating cooker (hereinafter, referred to simply as “heating cooker”) 400 according to Fifth Embodiment. The heating cooker 400 is an example of a dielectric heating apparatus according to an aspect of the present invention.

As shown in FIG. 17, the heating cooker 400 according to the present embodiment has a box-shaped body 431 having a front opening. The box-shaped body 431 includes a heating compartment (heating chamber) 2 in which an item to be heated is put through the opening. The front opening of the box-shaped body 431 is at an end portion on the front side of the heating compartment 2.

An insulating door (hereinafter, simply “door”) 432 that opens and closes the opening is provided on the front side of the box-shaped body 431. That is, the door 432 opens and closes the heating compartment 2. The door 432 has a window portion 434 that provides visual access to inside of the heating compartment 2 from outside of the heating cooker 400.

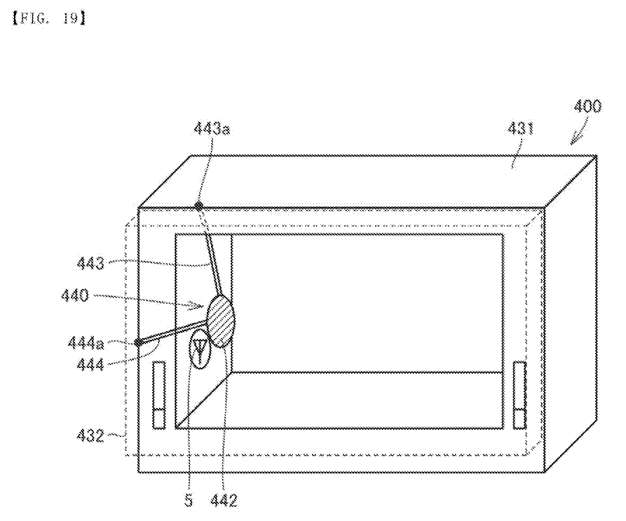

In the heating cooker 400 according to the present embodiment, an antenna 5 (high-frequency wave irradiator) for sending high-frequency waves that heat the material cooked in the heating compartment 2 is disposed on the left side of the heating compartment 2 (see FIG. 18). The antenna 5 sends a high-frequency signal into the heating compartment 2 through an aperture 441 formed in the left surface of the heating compartment 2.

A high-frequency power supply that generates a high-frequency signal is disposed in the left side wall of the box-shaped body 431, though not illustrated in the figure. The inner configuration of the heating cooker 100, including the high-frequency power supply, is basically the same as that of the heating cooker 1 according to First Embodiment. Accordingly, in the heating cooker 400, the same reference numerals will be used for elements having the same structures and functions as described for the heating cooker 1, and descriptions of such members are omitted.

The aperture 441 has an open/close mechanism 440. By the provision of the open/close mechanism 440, the aperture 441 can be brought to an open state or a blocked state. In the present embodiment, the open/close mechanism 440 is configured to close when the door 432 is open. The aperture 441 may be covered with a material that allows passage of electromagnetic waves (for example, a ceramic plate). When the aperture 441 is covered with such an electromagnetic-wave transmissive material, the open state of the aperture 441 is when the aperture 441 is covered with the electromagnetic-wave transmissive material, and the blocked state of the aperture 441 is when the aperture 441 is covered with the electromagnetic-wave transmissive material and the open/close mechanism 440 (specifically, a cover 442). That is, the aperture 441 passes electromagnetic waves in an open state.

The open/close mechanism 440 is configured from a cover 442, a first support shaft 443, and a second support shaft 444, among others.

The cover 442 is large enough to completely cover the aperture 441 (i.e., the cover 442 has an area slightly larger than the opening area of the aperture 441). The cover 442 may be formed from, for example, a metal plate. The cover 442 may be a metal plate that has been processed to block passage of microwaves (for example, by meshing or punching).

Preferably, an electromagnetic wave absorber is provided on the back of the cover 442 (the side facing the antenna 5). In this way, the electromagnetic wave absorber is able to absorb a high-frequency signal from the antenna 5 when the cover 442 is facing the antenna 5. With the electromagnetic wave absorber, the high-frequency signal from the antenna 5 can be prevented from being reflected off the back of the cover 442 into the antenna 5. The electromagnetic wave absorber may be made of various materials, including, for example, common fine carbon particles, ferrite materials, and carbon nanocoil composite materials.

The first support shaft 443 is connected at one end to the ceiling of the heating compartment 2. The other end is connected to an upper portion of the cover 442. The first support shaft 443 is movable toward and away from the back of the heating compartment 2 (arrow B in FIG. 18) by pivoting on a joint 443a connecting the first support shaft 443 to the ceiling of the heating compartment 2.

The second support shaft 444 is connected at one end to the back of the door 432. The other end is connected to a front portion of the cover 442. The second support shaft 444 makes movement as the door 432 opens and closes (arrow A in FIG. 18).

With this configuration, opening the door 432 moves forward the cover 422 of the open/close mechanism 440. In FIG. 18, the positions of the first support shaft 443 and the second support shaft 444 of the open/close mechanism 440 are indicated by solid lines for the door 432 closed, and by broken lines for the door 432 open. FIG. 17 shows the open/close mechanism 440 with the door 432 open. FIG. 19 shows the open/close mechanism 440 with the door 432 closed.

As shown in FIGS. 18 and 19, the aperture 441 is open (the aperture 441 is not covered by the cover 442) when the door 432 is closed. In this way, a high-frequency signal from the antenna 5 can be sent to the item to be heated inside the heating compartment 2.

When the door 432 is opened, the cover 442 of the open/close mechanism 440 moves forward, and completely covers the aperture 441 with the door 432 fully open (see FIG. 17). In this manner, in the heating cooker 400 of the present embodiment, the cover 442 moves and covers the aperture 441 in a coordinated fashion with opening of the door 432, making it possible to instantaneously block the high-frequency output to the heating compartment 2.

The heating cooker 400 of the present embodiment may further include an intensity detector that detects the intensity of high-frequency waves from the antenna 5. The open/close mechanism 440 may be controlled such that it closes when the high-frequency intensity detected by the intensity detector is above a predetermined value, regardless of whether the door 432 is open or closed.

The configuration of the present embodiment may be combined with the configuration of First or Second Embodiment. That is, the high-frequency output into the heating compartment may be physically blocked with the open/close mechanism in the configuration that stops the high-frequency oscillation circuit or the power supply to the semiconductor amplifier in the circuit of the high-frequency power supply. In this way, an even safer heating cooker can be provided.

In a variation of Fifth Embodiment, the open/close mechanism of the aperture may open and close under the control of the control unit. In this case, the control unit may actuate the open/close mechanism of the aperture according to the result of detection made by the door switch 9 in the manner described in First Embodiment.

A highly directional microwave such as semiconductor magnetron radiation poses high hazard when it is accidentally released to outside. However, safety can be ensured by applying the configuration of the present embodiment to a configuration that cuts off the AC power-supply line when the door is opened such as in traditional magnetron ranges.

The embodiments disclosed herein are to be considered in all aspects only as illustrative and not restrictive. The scope of the present invention is to be determined by the scope of the appended claims, not by the foregoing descriptions, and the invention is intended to cover all modifications falling within the equivalent meaning and scope of the claims set forth below. A configuration based on a combination of different configurations of the embodiments described in this specification is also intended to fall within the scope of the present invent ion.

### REFERENCE SIGNS LIST

1: Microwave heating cooker (dielectric heating apparatus)
2: Heating compartment (heating chamber)
3: First semiconductor amplifier
4: Second semiconductor amplifier
5: Antenna (high-frequency wave irradiator)
6: High-frequency oscillation circuit
9: Door switch (open/close detection unit)
9′: Door switch (open/close detection unit)
10: High-frequency power supply
10′: High-frequency power supply
20: Control unit
26: DC relay
32: Door
100: Microwave heating cooker (dielectric heating apparatus)
103: First semiconductor amplifier (first-stage semiconductor amplifier)
104: Second semiconductor amplifier (second-stage semiconductor amplifier)
106: High-frequency oscillation circuit
109: Door switch (first switch)
110: High-frequency power supply
126: DC relay (second switch)
200: Dielectric heating and thawing device (dielectric heating apparatus)
210: High-frequency power supply
251: Upper electrode (electrode)
252: Lower electrode (electrode)
300: Dielectric heating and thawing device (dielectric heating apparatus)
310: High-frequency power supply
400: Microwave heating cooker (dielectric heating apparatus)
432: Door
440: Open/close mechanism
441: Aperture

1. A dielectric heating apparatus comprising:
a door that opens and closes a heating chamber;
a high-frequency oscillation circuit;
at least one semiconductor amplifier for amplifying a high-frequency wave from the high-frequency oscillation circuit; and
a control unit or a switch that stops the high-frequency oscillation circuit when the door is opened.

2. A dielectric heating apparatus comprising:
a door that opens and closes a heating chamber;
a high-frequency oscillation circuit;
a plurality of semiconductor amplifiers for amplifying a high-frequency wave from the high-frequency oscillation circuit, and including at least a first-stage semiconductor amplifier and a second-stage semiconductor amplifier;
a first switch for switching ON and OFF power supply to the first-stage semiconductor amplifier; and
a second switch for switching ON and OFF power supply to the second-stage semiconductor amplifier,
the first switch being switched ON when the door is closed,
the first switch being switched OFF when the door is opened.

3. The dielectric heating apparatus according to claim 2, wherein the second switch is switched OFF after the first switch is switched OFF.

4. A dielectric heating apparatus comprising:
a heating chamber having an aperture;
a door that opens and closes the heating chamber;
a high-frequency oscillation circuit; and
a high-frequency wave irradiator that sends a high-frequency wave generated in the high-frequency oscillation circuit to the heating chamber through the aperture,
the aperture having an open/close mechanism,
the open/close mechanism of the aperture closing when the door is opened.

5. The dielectric heating apparatus according to claim 4, wherein the open/close mechanism has an electromagnetic wave absorber on a side facing the high-frequency wave irradiator.

6. The dielectric heating apparatus according to claim 1, wherein:
the high-frequency wave has a frequency of 0.3 GHz to 3 GHz, and
the dielectric heating apparatus includes an antenna that sends the high-frequency wave to an item to be heated.

7. The dielectric heating apparatus according to claim 1, wherein:
the high-frequency wave has a frequency of 3 MHz to 300 MHz,
the dielectric heating apparatus includes at least two electrodes between which is placed an item to be heated, and
the high-frequency wave creates a high-frequency electric field between said at least two electrodes.

8. The dielectric heating apparatus according to claim 2, wherein:
the high-frequency wave has a frequency of 0.3 GHz to 3 GHz, and
the dielectric heating apparatus includes an antenna that sends the high-frequency wave to an item to be heated.

9. The dielectric heating apparatus according to claim 4, wherein:
the high-frequency wave has a frequency of 0.3 GHz to 3 GHz, and
the dielectric heating apparatus includes an antenna that sends the high-frequency wave to an item to be heated.

10. The dielectric heating apparatus according to claim 2, wherein:
the high-frequency wave has a frequency of 3 MHz to 300 MHz,
the dielectric heating apparatus includes at least two electrodes between which is placed an item to be heated, and
the high-frequency wave creates a high-frequency electric field between said at least two electrodes.
